(19) United States
(12) Patent Application Publication
(10) Pub. No.: US 2019/0207113 A1
(43) Pub. Date: Jul. 4, 2019

(54) POLYTHIOPHENE DERIVATIVE, COMPOSITE AND MANUFACTURE METHOD THEREOF

(71) Applicant: Shenzhen China Star Optoelectronics Technology Co, Ltd., Shenzhen (CN)

(72) Inventor: Bao ZHA, Shenzhen (CN)

(21) Appl. No.: 15/945,069

(22) Filed: Apr. 4, 2018

Related U.S. Application Data
(63) Continuation of application No. PCT/CN2018/077088, filed on Feb. 24, 2018.

(30) Foreign Application Priority Data
Dec. 31, 2017 (CN) 201711499424.7

(51) Int. Cl. H01L 51/00; C08G 61/12; C08L 65/00; C08L 33/08; C08L 83/04; C08K 5/3415; C08K 5/32

(52) U.S. Cl. CPC H01L 51/0036; C08G 61/126; C08L 65/00; C08L 33/08; C08L 2205/03; C08K 5/3415; C08K 5/32; C08L 2203/20; C08L 83/04

(57) ABSTRACT

The present disclosure provides a polythiophene derivative, a composite and a manufacture method thereof. The composite is used for a substrate of Quantum dots and Organic Light Emitting Diode, and includes the polythiophene derivative and adulterating agents. A structural formula of the polythiophene derivative is the formula I below, wherein R is selected from one of a straight-chain alkane, a branched-chain alkane or a branched aromatic hydrocarbon, and wherein n represents the number of repeat units and may be a natural number within from 1 to 5000. Through the mean above, the present disclosure mitigates color mixing from confusion in QDs or luminescent materials of different colors and raises the color purity.

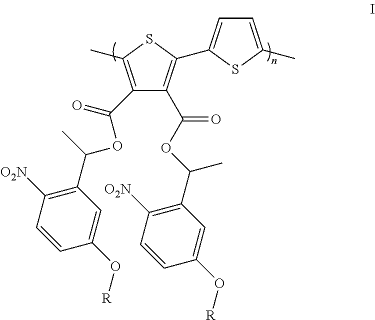

### RELATED APPLICATIONS

This application is a continuation application of PCT Patent Application No. PCT/CN2018/077088 filed on Feb. 24, 2018, which claims the priority benefit of Chinese Patent Application No. 201711499424.7, filed on Dec. 31, 2017, which is herein incorporated by reference in its entirety.

### FIELD OF THE DISCLOSURE

The present disclosure relates to technical field of illuminant material, and more particularly, to a polythiophene derivative, a composite and a manufacture method thereof.

### BACKGROUND

With speedy development of display technology, Quantum dots (ODs) and Organic Light Emitting Diode (OLED) both have unique superior function, as a next generation technology of display technology. At present, in the development of QDs and OLED technologies, a light emitting layer is generally made by ink jet printing.

During the long-term research and development; inventor of the present disclosure found that solution drops in which QDs materials or luminescent materials are dissolved easily drip onto a substrate, which easily brings on color mixing in adjacent QDs or luminescent materials of different colors, and affects the color purity.

### SUMMARY

The main technical issue addressed in the present disclosure is that a polythiophene derivative, a composite and a manufacture method thereof are provided to mitigate color mixing from confusion in QDs or luminescent materials of different colors and raise the color purity.

To solve above-mentioned technical issue, a scheme adopted in the present disclosure is: a composite used for a substrate of QDs and OLED is provided, which comprises polythiophene derivatives and adulterating agents; a structural formula of the polythiophene derivative is the formula I below; wherein the R shown in the formula I is selected from one of a straight-chain alkane, a branched-chain alkane or a branched aromatic hydrocarbon; the n shown in formula I represents the number of repeat units and may be a natural number within from 1 to 5000; the adulterating agent may be at least one of carbon black, dispersants, resins, polythiophene derivatives, monomers, photoinitiators, additives, and solvents; and the dispersant may be at least one of sorbitan fatty acid ester, octadecylamine, dodecylamine, polyoxyethylene sorbitan fatty acid ester, and alkylphenol-alkylamine formaldehyde condensate.

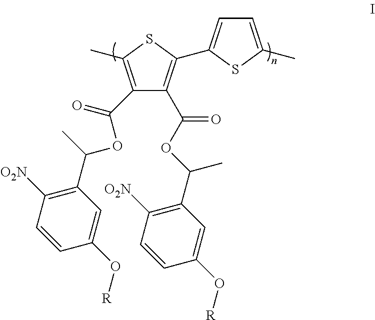

Another scheme adopted in the present disclosure is: a manufacture method of a polythiophene derivative is provided, which is used for manufacturing above-mentioned polythiophene derivative having a structural formula as shown in formula I above, and the method comprises: a compound II and a compound III is provided, followed by reacting the compound II with the compound III in a first polar solvent to manufacture a compound IV under a condition of weakly basic; a compound IV and a compound V is provided, then in the presence of a dehydrating agent and a first catalyst the compound IV reacts with the compound V in a second polar solvent to manufacture a compound VI; a compound VI and a compound VII is provided, then in the presence of a second catalyst the compound VI reacts with the compound VII in a non-polar solvent to manufacture a compound I; wherein, a structural formula of the compound II is the formula II below, a structural formula of the compound III is the formula III below, a structural formula of the compound IV is the formula IV below, a structural formula of the compound V is the formula V below, a structural formula of the compound VI is the formula VI below and a structural formula of the compound VII is the formula VII below, and wherein R shown in the formula III is selected from one of a straight-chain alkane, a branched-chain alkane or a branched aromatic hydrocarbon.

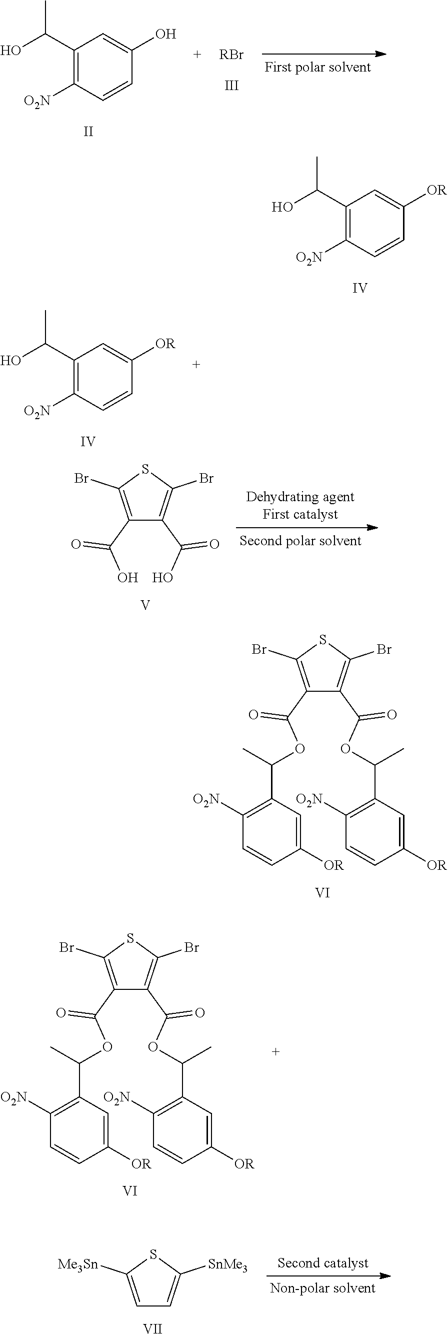

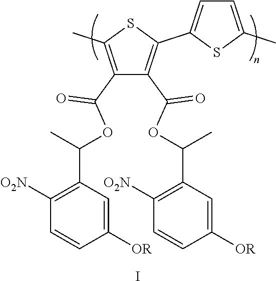

Yet another scheme adopted in the present disclosure is; a composite is provided, which is used for a substrate of QDs and OLEO, and the composite comprises the polythiophene derivatives in above-mentioned embodiments and adulterating agents.

Further another scheme adopted in the present disclosure is: a manufacture method of a composite is provided; which is used for a substrate of QDs and OLED, and the method comprises: by weight fraction; 18 to 22 parts of carbon black, 3 to 5 parts of dispersants, 5 to 8 parts of resins, 2 to 4 parts of polythiophene derivatives; 1 to 3 parts of monomers; 0.5 to 2 parts of photoinitiators, 1 to 3 parts of additives and 50 to 70 parts of solvents are respectively provided; the carbon black, the dispersants, the resins, the polythiophene derivatives, the monomers, the photoinitiators, the additives and the solvents are mixed to obtain a third mixture; the third mixture coats a glass substrate to form a composite layer; the composite layer is prebaked; the composite material layer is exposed through a predetermined mask; and the composite is obtained after developed.

Beneficial effects of the present disclosure are: different from the prior art, the present disclosure provides a polythiophene derivative having a structural formula as shown in formula I above; wherein the R shown in the formula I is selected from one of a straight-chain alkane, a branched-chain alkane or a branched aromatic hydrocarbon; and the n shown in formula I represents the number of repeat units which may be a natural number within from 1 to 5000. Through above-mentioned mean, a polythiophene derivative is obtained from the present disclosure, which has hydrophobicity. As shown in a following chemical equation, after exposed to ultraviolet light, it brings photodissociation reaction coming about at an ester group of the polythiophene derivative (formula I). As a result of two carboxyl groups existing in reaction products from photodissociation (formula VIII below), reaction products from photodissociation have hydrophilicity. That is, nature of the polythiophene derivative becomes from hydrophobicity (affinity for organic solvents) to hydrophilicity (organic solvent repellency) of photodissociation reaction products. Therefore, the polythiophene derivative; as a property changing material, can be added into a substrate. And during exposure process of ink jet printing, photodissociation happens to the polythiophene derivative excited by ultraviolet light, at this moment, the property of exposure area (surface of up layer) becomes hydrophilicity (organic solvent repellency). During ink jet printing process, liquid drops, where QDs materials or luminescent materials are dissolved, staying at the substrate decreases because of effect from organic solvent repellency of up layer surface. Therefore color mixing from confusion in QDs or luminescent materials of different colors can be mitigated and the color purity goes up.

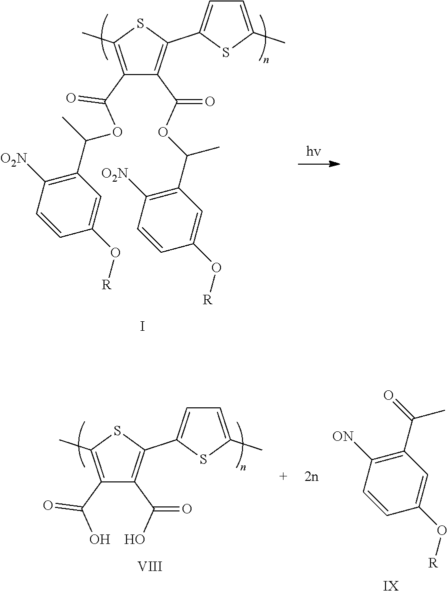

### BRIEF DESCRIPTION OF THE DRAWINGS

To more clearly illustrate embodiments of the application or technical solutions in the prior art, drawings to be used in the description of the embodiments of the application or the prior art will be briefly introduced hereinafter. Apparently, the drawings in the description below are merely some embodiments of the disclosure, a person skilled in the art can obtain other drawings according to these drawings without creative efforts. In the figures:

FIG. 1 is a schematic illustrating scheme for a manufacture method of a polythiophene derivative according to one embodiment;

FIG. 2 is a schematic illustrating scheme for step S102 of FIG. 1;

FIG. 3 is a schematic illustrating scheme for step S103 of FIG. 1;

FIG. 4 is a schematic illustrating scheme for a manufacture method of a composite according to one embodiment of the present disclosure;

FIG. 5 is a schematic illustrating structure for FIG. 4; and

FIG. 6 is a schematic illustrating local structure after exposed for FIG. 5.

### DETAILED DESCRIPTION OF PREFERRED EMBODIMENTS

The following will combine the drawings of the embodiments to further describe. Particularly, the following embodiments is only used to describe the present disclosure, but not limits the scope of the present disclosure, all of other embodiments obtained by the ordinary technical personnel in the art under the premise of no creative labor belong to the protective scope of the disclosure.

The experiment methods, for those not indicated in following embodiments, are selected as regular methods and conditions or as product specification.

The present disclosure provides a polythiophene derivative which has the structure as a following formula I:

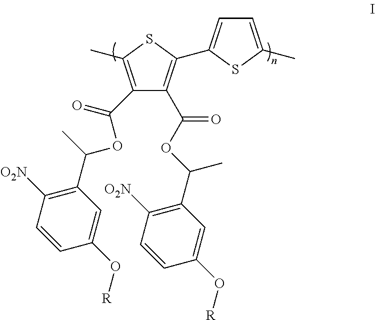

Wherein, “R” shown in the formula I may be a straight-chain alkane, a branched-chain alkane or a branched aromatic hydrocarbon.

Specifically, the alkane chain radical groups of straight-chain and branched-chain are composed of carbon and hydrogen atoms without unsaturated hydrocarbon, which have 1 to 12 carbon atoms and are attached to the rest of the molecule by a single bond. In the present embodiment, the alkyl groups may be methyl, ethyl, n-propyl, isopropyl, n-butyl, n-pentyl, tert-butyl, 3-methylhexyl, 2-methylhexyl, etc. Unless there are additional specific regulations in the specification, the alkyl group is replaced with arbitrary any selected from following radical groups: alkyl, alkenyl, halogen, haloalkenyl, cyano, nitro, aryl, cycloalkyl, heterocyclyl, heteroaryl, oxo, trimethylsilyl, —OR¹, —OC(O)—R¹, —N(R¹)₂, —C(O)R¹, —C(O)OR¹, —C(O)N(R¹)₂, —N(R¹)C(O)OR², —N(R¹)C(O)R², —N(R¹)S(O)ₜR² (where t is from 1 to 2), —S(O)ₜOR² (where t is from 1 to 2), —S(O)ₚR² (where p is from 0 to 2), —S(O)ₜN(R₁)₂ (where t is from 1 to 2), and wherein each R¹ is independently hydrogen, alkyl, haloalkyl, cycloalkyl, cycloalkylalkyl, aryl, aralkyl, heterocyclyl, heterocycloalkyl, heteroaryl, or heteroarylalkyl; and each R² is alkyl, haloalkyl, cycloalkyl, cycloalkylalkyl, aryl, aralkyl, heterocyclyl, heterocycloalkyl, heteroaryl, or heteroarylalkyl.

A branched aromatic hydrocarbon refers to a hydrocarbon ring system comprising hydrogen, 6 to 18 carbon atoms, at least one aromatic ring and directly attached to an alkyl. In the present embodiment, the branched aromatic hydrocarbon may be a monocyclic, bicyclic, tricyclic or tetracyclic systems directly attached to the alkyl, which may include a fused or bridged ring system. Unless there are additional specific regulations in the specification, the aryl is replaced with arbitrary any selected from following radical groups; alkyl, alkenyl, halogen, haloalkenyl, cyano, nitro, aryl, cycloalkyl, heterocyclyl, heteroaryl, oxo, trimethylsilyl, —OR¹, —OC(O)—R¹ , —N(R¹)₂ , —C(O)R¹, —C(O)OR¹, —C(O)N(R¹)₂, —N(R¹)C(O)OR², —N(R¹)C(O)R², —N(R¹)S(O)ₜR² (where t is from 1 to 2), —S(O)ₜOR² (where t is from 1 to 2), —S(O)ₚR² (where p is from 0 to 2), —S(O)ₜN(R¹)₂ (where t is from 1 to 2), and wherein each R¹ is independently hydrogen, alkyl, haloalkyl, cycloalkyl, cycloalkylalkyl, aryl, aralkyl, heterocyclyl, heterocycloalkyl, heteroaryl, or heteroarylalkyl; and each R² is alkyl, haloalkyl, cycloalkyl, cycloalkylalkyl, aryl, aralkyl, heterocyclyl, heterocycloalkyl, heteroaryl, or heteroarylalkyl.

The n shown in formula I represents the number of repeat units and may be a natural number within from 1 to 5000, specifically, the n may be 1000, 2000, 3000, 4000, and 5000, not limited herein.

Through above-mentioned mean, a polythiophene derivative is obtained from the present embodiment, which has hydrophobicity. As shown in a following chemical equation, after exposed to ultraviolet light, it brings photodissociation reaction coming about at an ester group of the polythiophene derivative (formula I). As a result of two carboxyl groups existing in reaction products from photodissociation (formula VIII below), reaction products from photodissociation have hydrophilicity. That is, nature of the polythiophene derivative becomes from hydrophobicity (affinity for organic solvents) to hydrophilicity (organic solvent repellency) of photodissociation reaction products. Therefore, the polythiophene derivative, as a property changing material, can be added into a substrate. And during exposure process of ink jet printing, photodissociation happens to the polythiophene derivative excited by ultraviolet light, at this moment, the property of exposure area (surface of up layer) becomes hydrophilicity (organic solvent repellency). During ink jet printing process, liquid drops, where QDs materials or luminescent materials are dissolved, staying at the substrate decreases because of effect from organic solvent repellency of up layer surface. Therefore color mixing from confusion in QDs or luminescent materials of different colors can be mitigated and the color purity goes up.

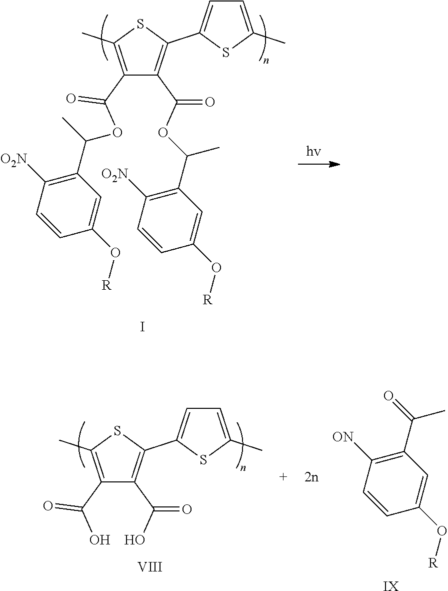

Wherein, in one embodiment, number-average molecular weight of the polythiophene derivative may be 12000-16000. For example, number-average molecular weight of the polythiophene derivative may be 12000, 13000, 14000, 15000, or 16000.

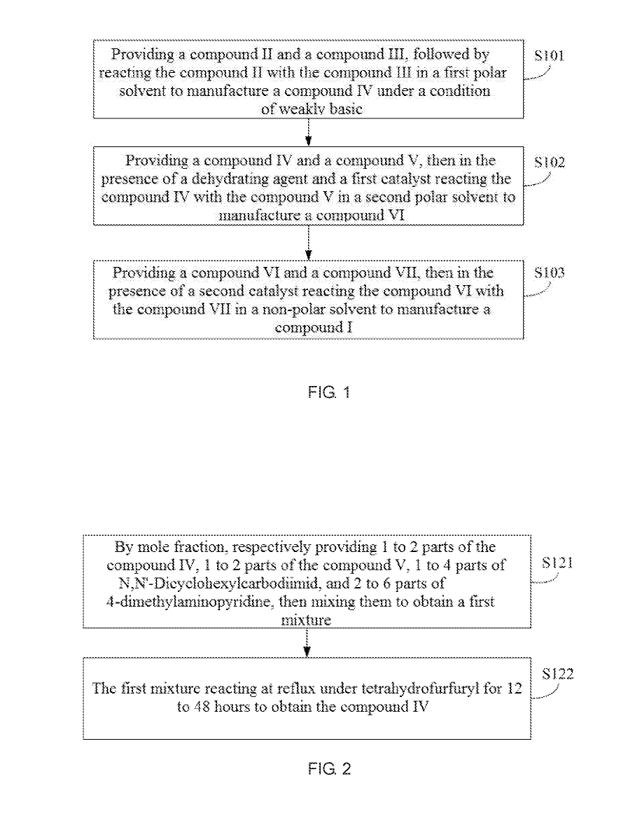

Referring to FIG. 1, which is a schematic illustrating scheme for a manufacture method of a polythiophene derivative according to one embodiment of the present disclosure. The present embodiment of the present disclosure provides a manufacture method of a polythiophene derivative, and the manufacture method is used for manufacturing above-mentioned polythiophene derivative. The method comprises:

Step S101: providing a compound II and a compound III, followed by reacting the compound II with the compound III in a first polar solvent to manufacture a compound IV under a condition of weakly basic.

Wherein, a structural formula of the compound II is the formula II below, and a structural formula of the compound III is the formula III below. The R shown in the formula III is selected from one of a straight-chain alkane, a branched-chain alkane or a branched aromatic hydrocarbon.

Specifically, in the present embodiment, the condition of weakly basic means a pH value of reaction system is within the range of 8 to 10. The condition of weakly basic forms with at least one alkali of C1-C4 carboxylates of alkaline earth metal, oxalates of alkaline earth metal, hydrogen phosphates of alkaline earth metal, phosphates of alkaline earth metal, and fluorides of alkaline earth metal. For example, at least one of sodium carbonate; potassium carbonate; sodium bicarbonate, potassium bicarbonate, sodium hydroxide, and potassium hydroxide could be added into the reaction system to control pH value of it to be within the range of 8 to 10. For example, the pH value may be 8, 9, or 10.

The first polar solvent may be, not limited herein, at least one of formamide, trifluoroacetic acid, dimethyl sulfoxide, acetonitrile, dimethylformamide, hexamethylphosphoramide, methanol, ethanol, acetic acid, isopropanol, pyridine; tetramethylethylenediamine, acetone, triethylamine, n-butanol, dioxane, tetrahydrofurfuryl alcohol, n-propanol, isobutanol, and tert-butanol.

Step S102: providing a compound IV and a compound V, then in the presence of a dehydrating agent and a first catalyst reacting the compound IV with the compound V in a second polar solvent to manufacture a compound VI.

Wherein, a structural formula of the compound IV is the formula IV below, and a structural formula of the compound V is the formula V below.

Specifically, in the present embodiment, the dehydrating agent may be carbodiimide or carbodiimide derivatives, such as carbodiimide, 1-(3-dimethylaminopropyl)-3-ethylcarbodiimide hydrochloride, and at least one of N,N′-diisopropylcarbodiimide or N,N′-dicyclohexylcarbodiimide.

The first catalyst may be at least one of 4-dimethylaminopyridine, concentrated sulfuric acid, cation exchange resin, and molecular sieve.

The second polar solvent may be, not limited herein, at least one of formamide, trifluoroacetic acid, dimethyl sulfoxide, acetonitrile, dimethylformamide, hexamethylphosphoramide, methanol, ethanol, acetic acid, isopropanol, pyridine, tetramethylethylenediamine, acetone, triethylamine, n-butanol, dioxane, tetrahydrofurfuryl alcohol, n-propanol, isobutanol, and tert-butanol.

Step S103: providing a compound VI and a compound VII, then in the presence of a second catalyst reacting the compound VI with the compound VII in a non-polar solvent to manufacture a compound I.

Wherein, a structural formula of the compound VI is the formula VI below, and a structural formula of the compound VII is the formula VII below.

Specifically, in the present embodiment, the second catalyst may be at least one of ZnCl₂, SnCl₂, FeCl₂, FeCl₃, Pd(dba)₂, and Pd₂(dba)₃, not limited herein.

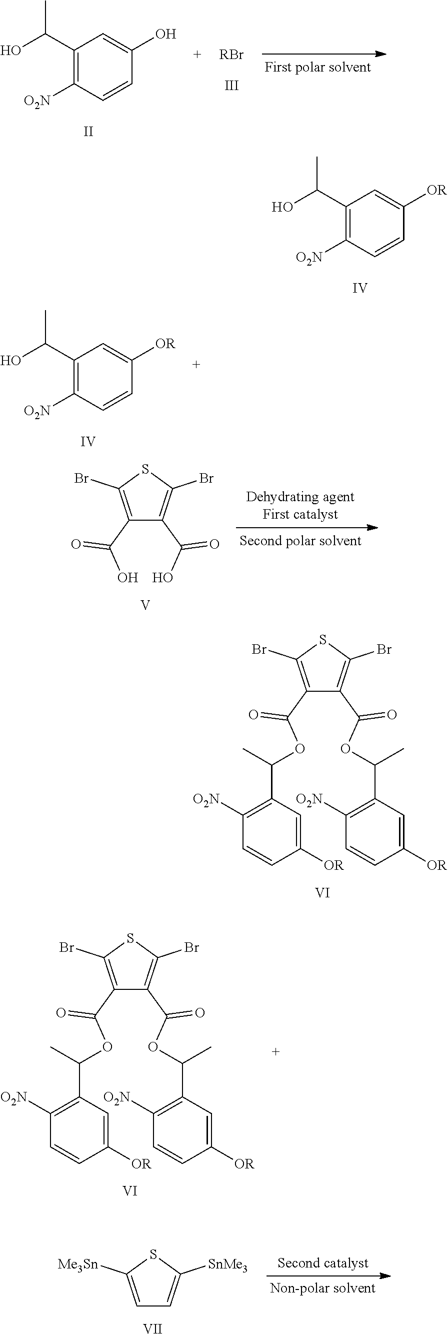

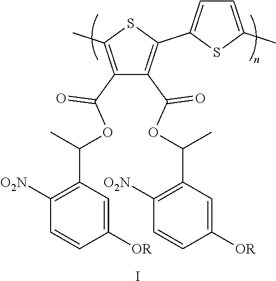

Wherein, in one embodiment, the dehydrating agent may be N,N′-Dicyclohexylcarbodiimide, the first polar solvent may be dimethylformamide, the second polar solvent may be tetrahydrofurfuryl, the non-polar solvent may be toluene, the first catalyst may be 4-dimethylaminopyridine and the second catalyst may be Pd₂(dba)₃.

Referring to FIG. 2, which is a schematic illustrating scheme for step S102 of FIG. 1. In the present embodiment, step S102 comprises:

Substep S121: by mole fraction, respectively providing 1 to 2 parts of the compound IV, 1 to 2 parts of the compound V, 1 to 4 parts of N,N′-Dicyclohexylcarbodiimid, and 2 to 6 parts of 4-dimethylaminopyridine, then mixing them to obtain a first mixture.

Specifically, in the present embodiment, the compound IV can be 1 or 2 parts, the compound V can be 1 or 2 parts, N,N′-Dicyclohexylcarbodiimid can be 1, 2, 3, or 4 parts and 4-dimethylaminopyridine can be 2, 3, 4, 5, or 6 parts.

Substep S122: the first mixture reacting at reflux under tetrahydrofurfuryl for 12 to 48 hours to obtain the compound IV.

Specifically, the reaction time may be 12, 24, 36, or 48 hours.

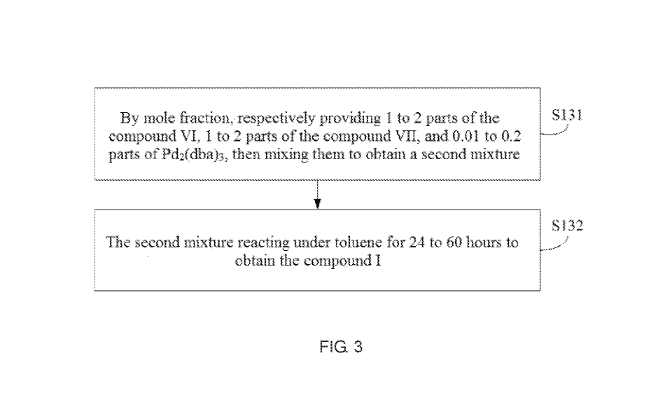

Referring to FIG. 3, which is a schematic illustrating scheme for step S103 of FIG. 1. In the present embodiment, step S103 comprises:

Substep S131: by mole fraction, respectively providing 1 to 2 parts of the compound VI, 1 to 2 parts of the compound VII, and 0.01 to 0.2 parts of Pd₂(dba)₃, then mixing them to obtain a second mixture.

Specifically, in the present embodiment, the compound VI can be 1 or 2 parts, the compound VII can be 1 or 2 parts, and Pd₂(dba)₃ can be 0.01, 0.05, 0.1, or 0.15 parts.

Substep S132: the second mixture reacting under toluene for 24 to 60 hours to obtain the compound I.

Specifically, the reaction time may be 24, 36, 48, or 60 hours. A degree of polymerization n of the compound I can be controlled via the reaction time.

An embodiment of the present disclosure provides a composite, which is used for a substrate of QDs and OLED, and the composite comprises the polythiophene derivative in above-mentioned embodiments and adulterating agents.

Specifically, in the present embodiment, the adulterating agent may be at least one of carbon black, dispersants, resins, polythiophene derivatives, monomers, photoinitiators, additives, and solvents.

Wherein, in one embodiment, materials of the composite, by weight fraction, comprises: 18 to 22 parts of carbon black, 3 to 5 parts of dispersants, 5 to 8 parts of resins, 2 to 4 parts of polythiophene derivatives, 1 to 3 parts of monomers, 0.5 to 2 parts of photoinitiators, 1 to 3 parts of additives and 50 to 70 parts of solvents.

Specifically, in the present embodiment, the carbon black can be 18, 19, 20, or 21 parts; the dispersant can be 3, 4, or 5 parts; the resin can be 5, 6, 7, or 8 parts; the polythiophene derivative can be 2, 3, or 4 parts; the monomer can be 1, 2, or 3 parts; the photoinitiator can be 0.5, 1, 1.5, or 2 parts; the additive can be 1, 2, or 3 parts; and the solvent can be 50, 60, or 70 parts.

Wherein, in one embodiment; the dispersant may be at least one of sorbitan fatty acid ester, octadecylamine, dodecylamine, polyoxyethylene sorbitan fatty acid ester, and alkylphenol-alkylamine formaldehyde condensate.

The resin type is an alkaline soluble resin and may be at least one resin of monocarboxylic acid, dicarboxylic acid resin and polyacid resin. The resin may be acrylic resins different in carbon chain length such as methacrylic resin, and ethacrylic resin. The resin may also be dicarboxylic acid resins such as maleic resin or phthalic resin. The resin may yet be polybasic acid resins such as a trimellitic acid resin, and a bis-benzene tetracarboxylic acid resin.

The monomer is an olefin derivative containing an unsaturated double bond.

Specifically, in the present embodiment, the olefin derivative comprises straight-chain or branched-chain hydrocarbon chain groups which are composed of carbon and hydrogen atoms, comprises at least one double bond, has 1 to 12 carbon atoms and are attached to the rest of the molecule by a single bond. In the present embodiment, alkenyl groups may be vinyl, prop-1-enyl, but-1-enyl, pent-1-enyl, pent-1, 4-dienyl, etc. Unless there are additional specific regulations in the specification the alkenyl group is replaced with arbitrary any selected from following radical groups: alkyl, alkenyl, halogen, haloalkenyl, cyano, nitro, aryl, cycloalkyl, heterocyclyl, heteroaryl, oxo, trimethylsilyl, —OR¹, —OC(O)—R¹, —N(R¹)₂, —C(O)R¹, —C(O)OR¹, —C(O)N(R¹)₂, —N(R¹)C(O)OR², —N(R¹)C(O)R², —N(R¹)S(O)ₜR² (where t is from 1 to 2), —S(O)ₜOR² (where t is from 1 to 2), —S(O)ₚR² (where p is from 0 to 2), —S(O)ₜN(R₁)₂ (where t is from 1 to 2), and wherein each R¹ is independently hydrogen, alkyl, haloalkyl, cycloalkyl, cycloalkylalkyl, aryl, aralkyl, heterocyclyl, heterocycloalkyl, heteroaryl, or heteroarylalkyl; and each R² is alkyl, haloalkyl, cycloalkyl, cycloalkylalkyl, aryl, aralkyl, heterocyclyl, heterocycloalkyl, heteroaryl, or heteroarylalkyl.

The photoinitiator may be at least one of 2,2′-bis(o-methylphenyl)-4,4′,5,5′-tetraphenyl-biimidazole, 2,2′-bis(o-ethylphenyl)-4,4′,5,5′-tetraphenyl-biimidazole, α,α-diethoxyacetophenone, and 2-methyl-2-morpholine-1-(4-methylphenylthio)propane-1-one.

The additive may be at least one of methylsiloxane and sodium polyacrylate.

The solvent may be at least one of propylene glycol monomethyl ether ester, butyl acetate, and 3-methoxy butyl acetate.

Through above-mentioned mean, the composite comprises a polythiophene derivative, wherein the polythiophene derivative is a hydrophobic (affinity for organic solvents) material. After exposed to ultraviolet light, it brings photodissociation reaction coming about at an ester group of the polythiophene derivative (formula I). As a result of two carboxyl groups existing in reaction products from photodissociation (formula VIII below), reaction products from photodissociation have hydrophilicity. That is, nature of the polythiophene derivative becomes from hydrophobicity (affinity for organic solvents) to hydrophilicity (organic solvent repellency) of photodissociation reaction products. Therefore, the polythiophene derivative, as a property changing material, can be added into a substrate. And during exposure process of ink jet printing, photodissociation happens to the polythiophene derivative excited by ultraviolet light, at this moment, the property of exposure area (surface of up layer) becomes hydrophilicity (organic solvent repellency). Lateral surface of the composite is not exposed, thus photocleavage reaction does not happen and the property of the lateral surface still has affinity for organic solvents. Liquid drops, where QDs materials or luminescent materials are dissolved, staying at the substrate decreases because of effect from organic solvent repellency of exposure area of the substrate (up layer surface). Therefore color mixing from confusion in QDs or luminescent materials of different colors can be mitigated and the color purity goes up.

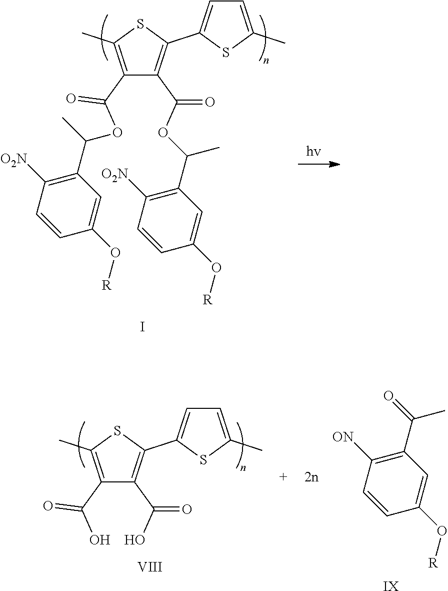

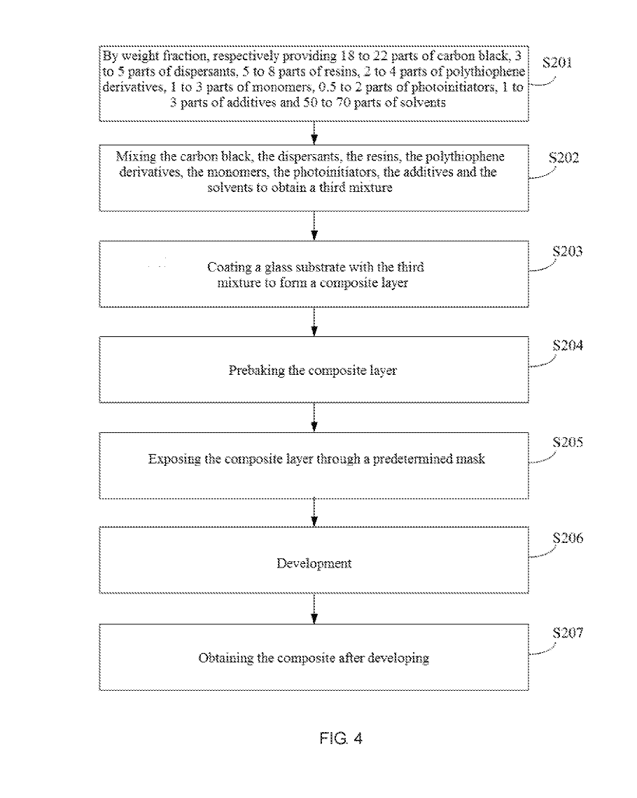

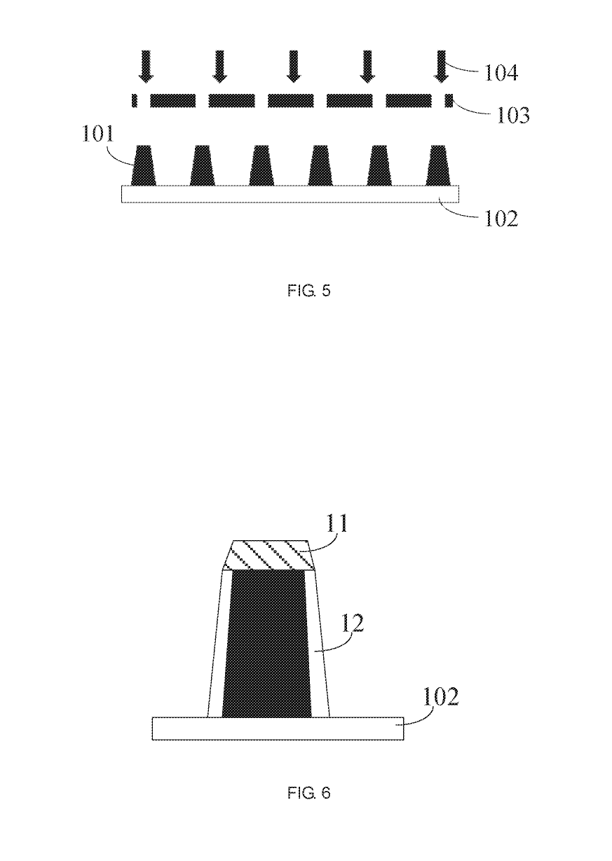

Referring to FIG. 4 to FIG. 6, FIG. 4 is a schematic illustrating scheme for a manufacture method of a composite according to one embodiment of the present disclosure; FIG. 5 is a schematic illustrating structure for FIG. 4; and FIG. 6 is a schematic illustrating local structure after exposed for FIG. 5.

An embodiment of the present disclosure provides a manufacture method of a composite, which is used for a substrate of QDs and OLED. The method comprises:

Step S201: by weight fraction, respectively providing 18 to 22 parts of carbon black, 3 to 5 parts of dispersants, 5 to 8 parts of resins, 2 to 4 parts of polythiophene derivatives, 1 to 3 parts of monomers, 0.5 to 2 parts of photoinitiators, 1 to 3 parts of additives and 50 to 70 parts of solvents.

Specifically, in the embodiment, the carbon black can be 18, 19, 20, or 21 parts; the dispersant can be 3, 4, or 5 parts; the resin can be 5, 6, 7, or 8 parts; the polythiophene derivative can be 2, 3, or 4 parts; the monomer can be 1, 2, or 3 parts; the photoinitiator can be 0.5, 1, 1.5, or 2 parts; the additive can be 1, 2, or 3 parts; and the solvent can be 50, 60, or 70 parts.

Step S202: mixing the carbon black, the dispersants, the resins, the polythiophene derivatives, the monomers, the photoinitiators, the additives and the solvents to obtain a third mixture.

Step S203: coating a glass substrate 102 with the third mixture to form a composite layer 101.

Specifically, in the embodiment, the third mixture coats the glass substrate 102 to form the composite layer 101.

Step S204: prebaking the composite layer 101.

Step S205: exposing the composite layer 101 through a predetermined mask 103.

Step S206: development.

Step S207: obtaining the composite after developing.

Specifically, the formulated third mixture in the present implementation is adapted for forming a composite film on a processable substrate (or processed substrate). The way of the implementation comprises a step of coating the processable substrate with the third mixture and prebaking it. These steps could be accomplished by known prior art. Upon specific purpose, the composite film can be formed with 10 nm to 2000 nm thickness. The coating step can be performing by spin coat and several other technologies by known prior art. When thickness of formed composite film is around or less than 150 nm, the most preferential way is spin coat to obtain uniform film thickness.

And then, such applied composite coat is prebaked to eliminate unnecessary solvents residual in the coat, for example, heated for 1 to 10 minutes on a hot plate. Specifically, the heating temperature can be 80° C., 90° C., 100° C., 110° C., 120° C., or 130° C. The heating time can be 1, 3, 5, 7, 9, or 10 minutes.

Subsequently, such a made composite film is formed with required pattern by being patternwise exposed. The exposure is performed through placing the mask 103 with required pattern onto the composite film and irradiating high energy radiation 104 (e.g., ultraviolet, excimer laser, or x-ray) or electron beam. The exposure may be performed by standard lithography or if desired, by immersion lithography of filling a liquid between the projection lens and the composite film. Wherein, during the exposure, a wavelength of irradiating ultraviolet may be 300 nm-380 nm, for example, the wavelength may be 300 nm, 330 nm, 360 nm, or 380 nm.

After exposure, the composite film is developed with a developer in a form of an aqueous alkaline solution for 0.1 to 0.3 minutes, by a standard technique such as dip, puddle or spray technique. For example, development time can be 0.1, 0.5, 1, 2, or 3 minutes. The developer is typically a 0.1 to 5 wt % aqueous solution of tetramethylammonium hydroxide (TMAH). For example, the developer is 0.1 wt %, 0.5 wt %, 2 wt %, 4 wt %, or 5 wt %. In this way, the desired pattern is formed on the substrate.

After development further followed by washing and drying, the pattern is sintered via baking, thus the composite is obtained. The post-development heat treatment can be performed with heating, at 90° C.-190° C., on a hot plate for 1 to 15 minutes, and specifically, the heating temperature may be 90° C., 110° C., 130° C., 150° C., 170° C., or 190° C. The heating time may be 1, 5, 10, or 15 minutes, such that sintering pattern follows the development.

Through above-mentioned mean, a composite comprising a polythiophene derivative is made, wherein the polythiophene derivative is a hydrophobic (affinity for organic solvents) material. After exposed to ultraviolet light, it brings photodissociation reaction coming about at an ester group of the polythiophene derivative (formula I). As a result of two carboxyl groups existing in reaction products from photodissociation (formula VIII below), reaction products from photodissociation have hydrophilicity. That is, nature of the polythiophene derivative becomes from hydrophobicity (affinity for organic solvents) to hydrophilicity (organic solvent repellency) of photodissociation reaction products. Therefore, the polythiophene derivative, as a property changing material, can be added into a substrate. And during exposure process of ink jet printing, photodissociation happens to the polythiophene derivative excited by ultraviolet light, at this moment, the property of exposure area 11 (surface of up layer) becomes hydrophilicity (organic solvent repellency). Lateral surface 12 of the composite is not exposed, thus photocleavage reaction does not happen and the property of the lateral surface 12 still has affinity for organic solvents. Liquid drops, where QDs materials or luminescent materials are dissolved, staying at the substrate decreases because of effect from organic solvent repellency of exposure area 11 of the substrate (up layer surface). Therefore color mixing from confusion in QDs or luminescent materials of different colors can be mitigated and the color purity goes up.

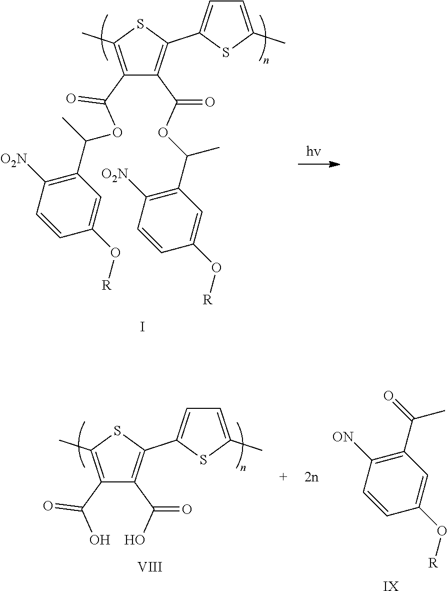

The method of the present disclosure is further described through following embodiments, but not limited within the scope of mentioned embodiments. Any improvement not beyond the spirit of the present disclosure should belong to the protection scope of the present disclosure.

### Embodiment 1

1 mmol of the compound IV, 2 mmol of the compound V, 2 mmol of N,N′-dicyclohexylcarbodiimide and 2 mmol of 4-dimethylaminopyridine are mixed to obtain the first mixture. The first mixture reacts at reflux under tetrahydrofurfuryl for 36 hours.

### Embodiment 2

0.5 mmol of the compound VI, 0.5 mmol of the compound VII and 0.025 mmol of Pd₂(dba)₃ are mixed to obtain the second mixture. The mixture reacts under toluene for 48 hours to obtain the compound I.

### Embodiment 3

The materials of the composite, by weight fraction, comprises: 18 parts of carbon black, 3 parts of dispersants, 5 parts of resins, 2 parts of polythiophene derivatives, 1 parts of monomers, 0.5 parts of photoinitiators, 1 parts of additives and 50 parts of solvents.

### Embodiment 4

The materials of the composite, by weight fraction, comprises: 22 parts of carbon black, 5 parts of dispersants, 8 parts of resins, 4 parts of polythiophene derivatives, 3 parts of monomers, 2 parts of photoinitiators, 3 parts of additives and 70 parts of solvents.

The foregoing descriptions are merely embodiments of the present disclosure, and therefore do not limit the scope of the present disclosure. Any variation of equivalent structure or equivalent scheme with the specification of the present disclosure and the accompanying drawings, or any directly or indirectly applied in other related technology fields are all considered within the scope patent protect defined by the claims of the present disclosure.

What is claimed is:

1. A composite used for a substrate of QDs and OLED, wherein the composite comprises polythiophene derivatives and adulterating agents;
wherein a structural formula of the polythiophene derivative is the formula I below;
wherein R shown in the formula I is selected from one of a straight-chain alkane, a branched-chain alkane or a branched aromatic hydrocarbon;
wherein n shown in formula I represents the number of repeat units and may be a natural number within from 1 to 5000;
wherein the adulterating agent may be at least one of carbon black, dispersants, resins, polythiophene derivatives, monomers, photoinitiators, additives, and solvents; and
wherein the dispersant may be at least one of sorbitan fatty acid ester, octadecylamine, dodecylamine, polyoxyethylene sorbitan fatty acid ester, and alkylphenol-alkylamine formaldehyde condensate.

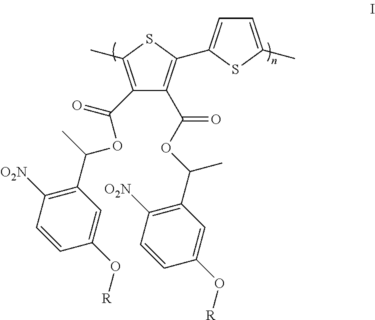

2. The composite according to claim 1, wherein materials of the composite, by weight fraction, comprises: 18 to 22 parts of carbon black, 3 to 5 parts of the dispersants, 5 to 8 parts of the resins, 2 to 4 parts of the polythiophene derivatives, 1 to 3 parts of the monomers, 0.5 to 2 parts of the photoinitiators, 1 to 3 parts of the additives and 50 to 70 parts of the solvents.

3. The composite according to claim 1, wherein the resin may be at least one of monocarboxylic acid resin, dicarboxylic acid resin and polyacid resin.

4. The composite according to claim 1, wherein the monomer is an olefin derivative containing an unsaturated double bond.

5. The composite according to claim 1, wherein the photoinitiator may be at least one of 2,2′-bis(o-methylphenyl)-4,4′,5,5′-tetraphenyl-biimidazole, 2,2′-bis(o-ethylphenyl)-4,4′,5,5′-tetraphenyl-biimidazole, α,α-diethoxyacetophenone, and 2-methyl-2-morpholine-1-(4-methylphenylthio)propane-1-one.

6. The composite according to claim 1, wherein the additive may be at least one of methylsiloxane and sodium polyacrylate.

7. The composite according to claim 1, wherein the solvent may be at least one of propylene glycol monomethyl ether ester, butyl acetate, and 3-methoxy butyl acetate.

8. A polythiophene derivative has a structural formula shown in formula I below, wherein R shown in the formula I is selected from one of a straight-chain alkane, a branched-chain alkane or a branched aromatic hydrocarbon, and n shown in formula I represents the number of repeat units and may be a natural number within from 1 to 5000.

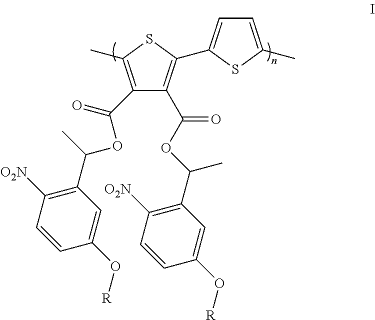

9. The polythiophene derivative according to claim 8, wherein a number-average molecular weight of the polythiophene derivative may be 12000 to 16000.

10. The polythiophene derivative according to claim 9, wherein a number-average molecular weight of the polythiophene derivative may be 13000.

11. The polythiophene derivative according to claim 9, wherein a number-average molecular weight of the polythiophene derivative may be 14000.

12. The polythiophene derivative according to claim 9, wherein a number-average molecular weight of the polythiophene derivative may be 15000.

13. A manufacture method of a polythiophene derivative for manufacturing the polythiophene derivative according to claim 8, wherein a structural formula of it is formula I according to claim 8, and the method comprises:
providing a compound II and a compound III, followed by reacting the compound II with the compound III in a first polar solvent to manufacture a compound IV under a condition of weakly basic;
providing a compound IV and a compound V, then in the presence of a dehydrating agent and a first catalyst reacting the compound IV with the compound V in a second polar solvent to manufacture a compound VI;
providing a compound VI and a compound VII, then in the presence of a second catalyst reacting the compound VI with the compound VII in a non-polar solvent to manufacture a compound I;
wherein a structural formula of the compound II is the formula II below, a structural formula of the compound III is the formula III below, a structural formula of the compound IV is the formula IV below, a structural formula of the compound V is the formula V below, a structural formula of the compound VI is the formula VI below and a structural formula of the compound VII is the formula VII below; and
wherein R shown in the formula III is selected from one of a straight-chain alkane, a branched-chain alkane or a branched aromatic hydrocarbon.

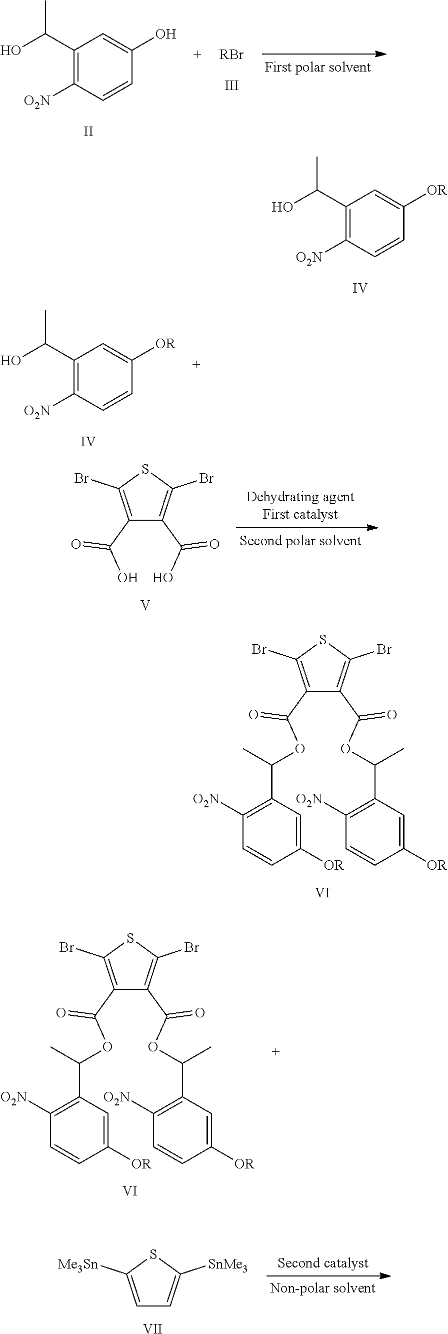

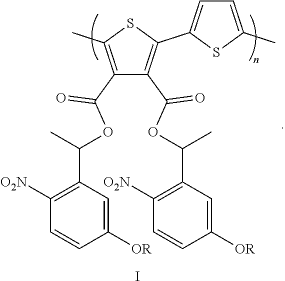

14. The manufacture method according to claim 13, wherein the condition of weakly basic has a pH value of 8 to 10.

15. The manufacture method according to claim 14, wherein the condition of weakly basic has a pH value of 9.

16. The manufacture method according to claim 13, wherein the dehydrating agent is N,N′-Dicyclohexylcarbodiimide, the first polar solvent is dimethylformamide, the second polar solvent is tetrahydrofurfuryl, the non-polar solvent is toluene, the first catalyst is 4-dimethylaminopyridine and the second catalyst is Pd₂(dba)₃.

17. The manufacture method according to claim 16, wherein the step of providing a compound IV and a compound V, then in the presence of a dehydrating agent and a first catalyst reacting the compound IV with the compound V in a second polar solvent further comprises:
by mole fraction, respectively providing 1 to 2 parts of the compound IV, 1 to 2 parts of the compound V, 1 to 4 parts of N,N′-Dicyclohexylcarbodiimid, and 2 to 6 parts of 4-dimethylaminopyridine, then mixing them to obtain a first mixture; and
the first mixture reacting at reflux under tetrahydrofurfuryl for 12 to 48 hours to obtain the compound IV.

18. The manufacture method according to claim 17, wherein the step of the first mixture reacting at reflux under tetrahydrofurfuryl for 12 to 48 hours comprises:
the first mixture reacting at reflux under tetrahydrofurfuryl for 36 hours.

19. The manufacture method according to claim 16, wherein the step of providing a compound VI and a compound VII, then in the presence of a second catalyst reacting the compound VI with the compound VII in a non-polar solvent further comprises:
by mole fraction, respectively providing 1 to 2 parts of the compound VI, 1 to 2 parts of the compound VII, and 0.01 to 0.2 parts of Pd₂(dba)₃, then mixing them to obtain a second mixture; and
the second mixture reacting under toluene for 24 to 60 hours to obtain the compound I.

20. The manufacture method according to claim 19, wherein the step of the second mixture reacting under toluene for 24 to 60 hours comprises:
the second mixture reacting under toluene for 58 hours.
